(19) United States
(12) Patent Application Publication
(10) Pub. No.: US 2019/0300434 A1
(43) Pub. Date: Oct. 3, 2019

(54) Method of Fabricating High-Permittivity Dielectric Material

(71) Applicant: United States of America as represented by the Administrator of NASA, Washington, DC (US)

(72) Inventors: Dennis Stephen Tucker, Huntsville, AL (US); Terry D. Rolin, Elkmont, AL (US); Curtis W. Hill, Meridianville, AL (US)

(21) Appl. No.: 15/940,143

(22) Filed: Mar. 29, 2018

(51) Int. Cl. C04B 35/468; C23C 16/40; C23C 16/455; C04B 35/628; C04B 35/645

(52) U.S. Cl. CPC C04B 35/4682; C04B 2235/6021; C23C 16/45525; C04B 35/62807; C04B 35/62884; C04B 35/62897; C04B 35/645; C04B 2235/3236; C04B 2235/3418; C04B 2235/5454; C04B 2235/6565; C04B 2235/6581; C04B 2235/666; C04B 2235/6567; C23C 16/402

(57) ABSTRACT

Nano-sized powder particles of barium titanate are coated with silica yielding silica-coated particles having a silica coating thickness in a range of 2-5 nanometers. The silica-coated particles are sintered by application of pressure in a range of 35-50 megapascals and temperature in a range of 950-1050° C. The sintered quantity of material is cooled at a cooling rate in a range of 1-3° C. per minute at least until the temperature thereof is less than 120° C.

### ORIGIN OF THE INVENTION

The invention described herein was made in the performance of work under a NASA contract and by an employee of the United States Government and is subject to the provisions of Public Law 96-517 (35 U.S.C. § 202) and may be manufactured and used by or for the Government for governmental purposes without the payment of any royalties thereon or therefore.

### BACKGROUND OF THE INVENTION

### 1. Field of the Invention

This invention relates to fabricating dielectric materials. More specifically, the invention is method for fabricating barium titanate-based dielectric materials having high permittivity and low dielectric loss with high energy density.

### 2. Description of the Related Art

Increasing the amount of power, and the length of time a battery can supply power for a load, is a constant challenge. For example, air and space missions continually dictate the need for more power as missions lengthen in time and complexity. Currently, electrochemical batteries are the primary power source for avionics and their subsystems. Current state-of-the-art electrochemical rechargeable batteries cannot be rapidly charged, contain harmful chemicals, and have fairly limited life spans. A positive advancement in this art would involve the replacement of heavier/larger electrochemical batteries with lighter, safer, and more efficient energy-storage devices.

Solid-state ultracapacitors are recyclable energy-storage devices that have shown promise in terms of increased power and number of charging cycles as compared to electrochemical batteries. Unfortunately, current solid-state ultracapacitors do not possess sufficient permittivity and energy density to justify their use as a replacement for electrochemical batteries.

### SUMMARY OF THE INVENTION

Accordingly, it is an object of the present invention to provide a method of fabricating high-permittivity dielectric materials for use in ultracapacitors.

Another object of the present invention is to provide a method of fabricating dielectric materials for use in solid-state ultracapacitors such that the fabricated material exhibits a high-permittivity and high energy density.

Other objects and advantages of the present invention will become more obvious hereinafter in the specification and drawings.

In accordance with the present invention, a method of fabricating a high-permittivity dielectric material includes the step of coating nano-sized powder particles of barium titanate with silica yielding silica-coated particles having a silica coating thickness in a range of 2-5 nanometers. The silica-coated particles are sintered by application of pressure in a range of 35-50 megapascals and temperature in a range of 950-1050° C. The sintered quantity of material is cooled at a cooling rate in a range of 1-3° C. per minute at least until the temperature thereof is less than 120° C.

### BRIEF DESCRIPTION OF THE DRAWING(S)

Other objects, features and advantages of the present invention will become apparent upon reference to the following description of the preferred embodiments and to the drawings, wherein corresponding reference characters indicate corresponding parts throughout the several views of the drawings and wherein:

FIG. 1 is a schematic view of a method of fabricating a high-permittivity dielectric material in accordance with an embodiment of the present invention;

FIG. 2 is a plot of permittivity and loss tangent as a function of frequency for a first material sample fabricated in accordance with the present invention;

FIG. 3 is a plot of permittivity and loss tangent as a function of frequency for a second material sample fabricated in accordance with the present invention;

FIG. 4 is a plot of permittivity and loss tangent as a function of frequency for a third material sample fabricated in accordance with the present invention;

FIG. 5 is a plot of permittivity and loss tangent as a function of frequency for a fourth material sample fabricated in accordance with the present invention; and

FIG. 6 is a plot of permittivity and loss tangent as a function of frequency for a fifth material sample fabricated in accordance with the present invention.

### DESCRIPTION OF THE PREFERRED EMBODIMENT(S)

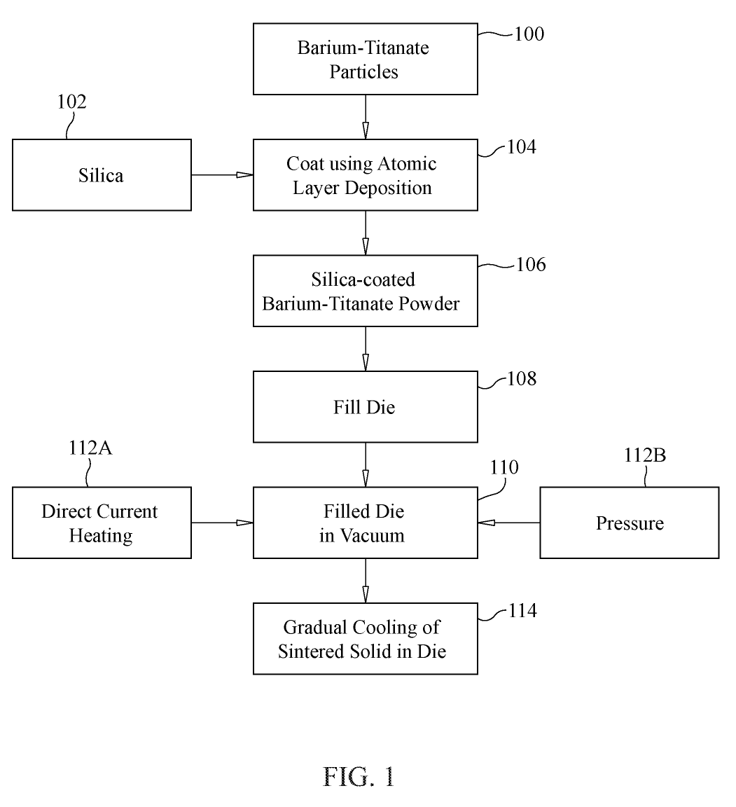

Referring now to the drawings and more particularly to FIG. 1, steps in a fabrication process are shown that yield a high-permittivity dielectric material in accordance with an embodiment of the present invention. As will be explained further below, the resulting material possesses characteristics and specifications that will allow it to be used in solid-state ultracapacitor energy-storage devices whose performance will match or exceed that of comparable electrochemical batteries. Accordingly, dielectric materials made in accordance with the present invention can become the building block for solid-state ultracapacitors for use in the next generation of energy-storage devices.

The constituent elements used to make the material in accordance with the present invention are nano-sized particles of barium-titanate 100 and silicon dioxide or silica 102 as it will be referred to hereinafter. As used herein, nano-sized particles are defined as particles having diameters in the range of approximately 20 nanometers to approximately 500 nanometers.

At a coating process step 104, silica 102 is used to coat barium-titanate particles 100 using the vapor deposition technique known as atomic layer deposition. For purposes of the present invention, step 104 is carried out to achieve a solid silica coating thickness targeted to be in the range of 2-5 nanometers on the nano-sized particles of barium-titanate. The resulting silica-coated barium-titanate powder 106 is next processed to form a solid.

Powder 106 is used to fill a die at step 108 where the shape and size of the die are not limitations of the present invention. The die can be made from a variety of materials to include graphite. Graphite is typically used as a die material owing to a number of attributes to include high thermal conductivity, durability, good material release properties, and its generally inert relationship with respect to most materials.

The filled die is placed in a vacuum at step 110. The silica-coated barium-titanate powder is then simultaneously subjected to increase in temperature and pressure at steps 112A and 112B, respectively, to thereby sinter the silica-coated barium-titanate powder into a solid form thereof. More specifically, heating step 112A is accomplished by applying a direct electric current to the die in order to raise the temperature of the silica-coated barium-titanate powder (i.e., starting out at room temperature) to a temperature in the range of 950-1050° C. Measurement of temperature can be accomplished in a variety of ways (e.g., using a thermocouple, optical pyrometer, etc.) without departing from the scope of the present invention. The applied current is controlled such that heating follows a ramping function in a range of 5 ft-100° C. per minute. The simultaneous application of pressure step 112B also follows a ramping function to achieve a pressure in the range of 35-50 megapascals (1\1 Pa). A pressure ramping function of approximately 10 MPa per minute can be used. Once the target temperature and pressure are achieved, the combination is maintained for approximately 5 minutes to assure complete sintering of the powder in the die.

At the completion of the above-described sintering process, the electric current is turned off and the pressure is released. The sintered or solid form of silica-coated barium-titanate is gradually cooled at step 114. More specifically, the solid material is passively cooled in the die in accordance with a cooling ramping function in a range of 1-3° C. per minute at least until the temperature of the solid is at or below 120° C. The gradual cooling through the 120° C. temperature minimizes the effects of a structural transformation in the sintered solid that could cause a macro break-up of the sintered solid.

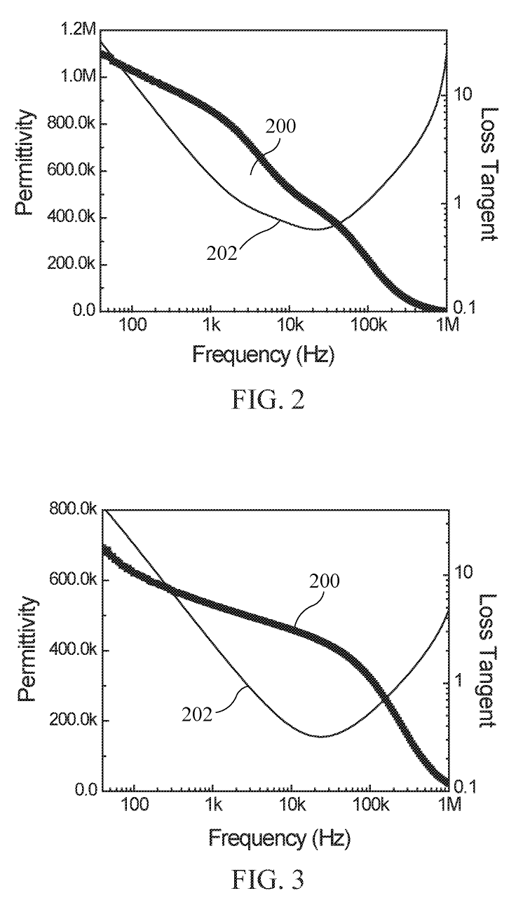

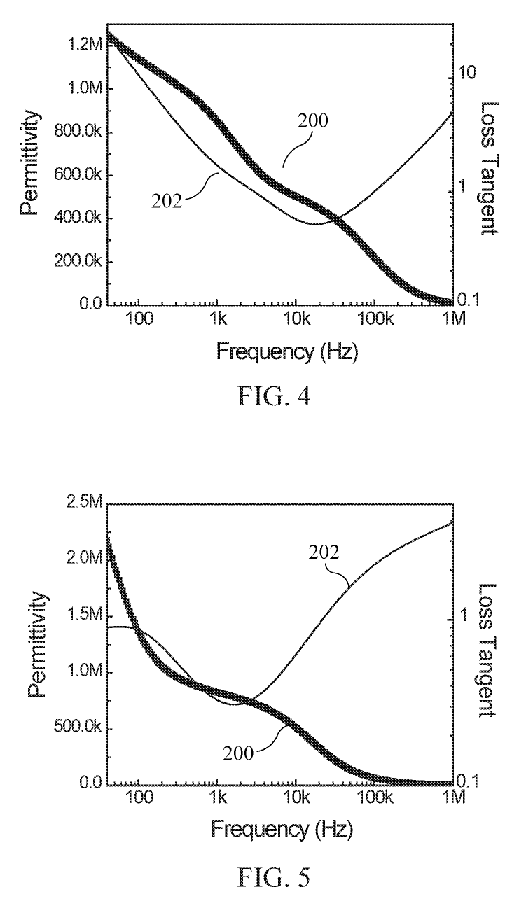

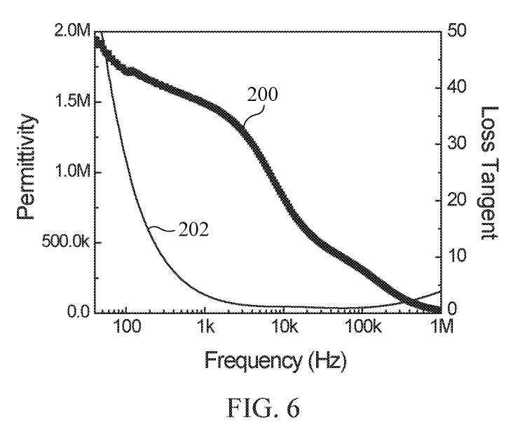

Numerous samples fabricated in accordance with the present invention were tested with the results for five samples being indicated in the table below for the nominal testing frequency of Broadband performance characteristics of the fabricated materials are presented in the corresponding plots of permittivity and loss tangent as a function of frequency are illustrated for samples 1-5 in FIG. 2-6, respectively. Particle sizes of the barium-titanate for all samples were approximately 140 nanometers. A silica coating thickness of 5 nanometers was targeted for each sample.

Each silica-coated barium-titanate sample was heated in a die using direct current in the following three-phase process:
heating at a rate of 100° C. per minute until the sample reached. 950° C.;
holding the temperature at 950° C. for 2 minutes; and
heating at a rate of 50° C. per minute until the sample reached 1050° C.
   Simultaneous with heating of the sample, the pressure applied to the filled die followed the following three-phase process
pressure applied at a rate of 10 MPa per minute until the pressure reached 35 MPa;
holding pressure at 35 MPa until completion of 2 minutes of temperature hold at 950° C.; and
pressure applied at a rate of 10 MPa per minute until the pressure reached 50 MPa.

Once each sample attained the temperature/pressure combination of 1050° C./50 MPa, each sample was held at this temperature/pressure combination for 5 minutes. At the conclusion of 5 minutes, the direct current was removed and the pressure was released to 0 MPa. Each sample was allowed to cool at a rate of 1-3° C. down to at least 120° C. in order to avoid sample fracturing. Each sample was removed from its die upon reaching room temperature.

| Sample | Permittivity @ 1 kHz | Loss Tangent @ 1 kHz |
|---|---|---|
| 1 | 856,536 | 1.777 |
| 2 | 529,577 | 2.294 |
| 3 | 846,779 | 1.691 |
| 4 | 827,393 | 0.327 |
| 5 | 1,487,486 | 3.222 |

As is evident from the results, the smallest permittivity was in excess of 500,000, while the largest permittivity was nearly 1.5 million. The semiconducting barium-titanate particles in the sintered solid are separated by thin regions of silica such that electric charge can move easily within the barium-titanate particles, while the regions of silica store the electric charge.

All samples were fabricated the same way. However, variations in coating thickness resulted in corresponding variations in permittivity since samples having a greater coating thickness (i.e., greater than the target 5 nanometer thickness) reduce permittivity and increase the loss tangent. The corresponding plots of permittivity and loss tangent for each of samples 1-5 are shown in FIGS. 2-6, respectively, where curve 200 in each figure is a plot of permittivity as a function of frequency, and curve 202 in each figure is a plot of loss tangent as a function of frequency.

The advantages of the present invention are numerous. The fabrication method yields solid-state dielectric materials that can be used to construct solid-state ultracapacitor energy-storage devices. The materials exhibit high permittivity that is indicative of a high energy density through capacitance. The low loss tangent results are indicative of low losses of stored electric charges. Given that the maximum permittivity of barium-titanate is on the order of 10,000, the method of the present invention will substantially advance the art of solid-state ultracapacitors.

Although the invention has been described relative to a specific embodiment thereof, there are numerous variations and modifications that will be readily apparent to those skilled in the art in light of the above teachings. It is therefore to be understood that, within the scope of the appended claims, the invention may be practiced other than as specifically described.

What is claimed as new and desired to be secured by Letters Patent of the United States is:

1. A method of fabricating a high-permittivity dielectric material, comprising the steps of:
coating nano-sized powder particles of barium titanate with silica yielding silica-coated particles having a silica coating thickness in a range of 2-5 nanometers;
sintering a quantity of said silica-coated particles by application of pressure in a range of 35-50 megapascals and temperature in a range of 950-1050° C.; and
cooling said quantity so-sintered at a cooling rate in a range of 1-3° C. per minute at least until a temperature of said quantity so-sintered is less than 120° C.

2. A method according to claim 1, wherein said step of coating comprises atomic layer deposition of said silica onto said nano-sized powder particles of barium titanate.

3. A method according to claim 1, wherein said step of sintering comprises a direct current sintering process.

4. A method according to claim 1, wherein said step of sintering takes place in a vacuum.

5. A method according to claim 1, wherein said step of sintering includes the step of increasing said pressure in accordance with a pressure ramping function.

6. A method according to claim 1, wherein said step of sintering includes the step of increasing said temperature in accordance with a temperature ramping function.

7. A method according to claim 1, wherein said step of sintering includes the step of maintaining said quantity of said silica-coated particles at said pressure and said temperature for approximately 5 minutes.

8. A method of fabricating a high-permittivity dielectric material, comprising the steps of:
coating, using atomic layer deposition, nano-sized powder particles of barium titanate with silica yielding silica-coated particles having a silica coating thickness in a range of 2-5 nanometers;
sintering, using direct current sintering in a vacuum, a quantity of said silica-coated particles by application of pressure in a range of 35-50 megapascals and temperature in a range of 950-1050° C.; and
cooling said quantity so-sintered at a cooling rate in a range of 1-3° C. per minute at least until a temperature of said quantity so-sintered is less than 120° C.

9. A method according to claim 8, wherein said step of sintering includes the step of increasing said pressure in accordance with a pressure ramping function.

10. A method according to claim 8, wherein said step of sintering includes the step of increasing said temperature in accordance with a temperature ramping function.

11. A method according to claim 8, wherein said step of sintering includes the step of maintaining said quantity of said silica-coated particles at said pressure of 50 megapascals and said temperature of 1050° C. for approximately 5 minutes.

12. A method of fabricating a high-permittivity dielectric material, comprising the steps of:
coating, using atomic layer deposition, nano-sized powder particles of barium titanate with silica yielding silica-coated particles having a silica coating thickness in a range of 2-5 nanometers;
placing a quantity of said silica-coated particles in a die;
placing said die in a vacuum;
increasing pressure on said die to achieve a sintering pressure on said quantity of said silica-coated particles in said die of 50 megapascals;
applying, simultaneously with said step of increasing, a direct current to said die to achieve a sintering temperature of said quantity of said silica-coated particles in said die of 1050° C.;
maintaining said sintering pressure and said sintering temperature for approximately 5 minutes wherein said quantity of said silica-coated particles in said die are transformed to a sintered solid; and
cooling said sintered solid at a cooling rate in a range of 1-3° C. per minute at least until a temperature of said sintered solid is less than 120° C.

13. A method according to claim 12, wherein said step of increasing includes the step of increasing said sintering pressure on said die in accordance with a pressure ramping function.

14. A method according to claim 12, wherein said step of applying includes the step of increasing said sintering temperature in accordance with a temperature ramping function.
